(19) United States
(12) Patent Application Publication
(10) Pub. No.: US 2024/0410993 A1
(43) Pub. Date: Dec. 12, 2024

(54) Process, Voltage, Time Invariant Compensation Loop for High Precision Propagation Delay in Multi-Channel Lidar Applications

(71) Applicant: STMicroelectronics International N.V., Geneva (CH)

(72) Inventors: Alessandro NICOLOSI, Dresano (IT); Andrea GAMBERO, Milano (IT); Juri GIOVANNONE, Cernobbio (IT)

(21) Appl. No.: 18/330,914

(22) Filed: Jun. 7, 2023

(51) Int. Cl. G01S 7/4865; G01S 17/10; G01S 17/894

(52) U.S. Cl. CPC G01S 7/4865; G01S 17/10; G01S 17/894

(57) ABSTRACT

An electronic system and method for generating a pulsed illumination signal in a multi-channel LIDAR application is provided. An example electronic system includes a pulsed signal generator, a pulse emitting circuit, and an illumination source. The pulsed signal generator includes a main switch, a selection switch controlling the flow of current to the illumination source, and a switching control circuit. The switching control circuit configured to receive an illumination source enabled signal indicating a difference between a duration of the illumination source enabled signal and a target duration of the illumination source enabled signal. The switching control circuit is configured to receive the duration target code and determine a main switch enable signal configured to activate the main switch and a selection switch enable signal configured to activate the selection switch, based at least in part on the duration target code and a target overlap.

### TECHNOLOGICAL FIELD

Embodiments of the present disclosure relate generally to propagation loops to carry out high precision timing in multi-channel light detection and ranging (LIDAR) applications, and more particularly, to a process voltage and time (PVT) invariant propagation loop for high precision, multi-channel LIDAR applications.

### BACKGROUND

Various example embodiments address technical problems associated with generating electronic pulse signals to power a laser diode, particularly in a multi-channel LIDAR applications. In general, multi-channel LIDAR applications include multiple laser diodes used to generate very short (approximately 1 nanosecond), high current (up to 40 amps each) pulses. These pulses are directed by an optic system, typically including two micro-electromechanical (MEMS) mirrors for horizontal and vertical scanning, toward a target environment. The system further includes a receiver (e.g., a Single-Photon Avalanche Diode) positioned to receive the pulses as they reflect off various obstacles in the environment. The reception of the pulses enables the system to measure the time-of-flight (ToF) of the pulse and determine obstacle distances, enabling the system to reconstruct a 3D image of the target environment.

Applicant has identified many technical challenges and difficulties associated with generating a pulsed illumination signal. Through applied effort, ingenuity, and innovation, Applicant has solved problems related to generating high precision and PVT invariant pulsed illumination signal which are described in detail below.

### BRIEF SUMMARY

Various embodiments are directed to example systems and methods for generating a pulsed illumination signal in a multi-channel LIDAR application. In accordance with some embodiments of the present disclosure, an example electronic system is provided. In some embodiments, the example electronic system may comprise a pulse emitting circuit electrically connected to an illumination source. The example electronic system may further include a pulsed signal generator. In some embodiments, the pulsed signal generator may comprise a main switch electrically connected to the pulse emitting circuit, a selection switch electrically connected to the main switch, and a switching control circuit. In some embodiments, the selection switch controls a current flow to the illumination source. In some embodiments, the switching control circuit may comprise a first control circuit, wherein the first control circuit receives an illumination source enabled signal indicating a status of the illumination source, and wherein the first control circuit generates a duration target code indicative of a comparison between a duration of the illumination source enabled signal and a target duration of the illumination source enabled signal. In addition, in some embodiments, the switching control circuit may comprise a second control circuit, wherein the second control circuit receives the duration target code, and wherein the second control circuit determines a main switch enable signal configured to activate the main switch and a selection switch enable signal configured to activate the selection switch, based at least in part on the duration target code and a target overlap.

In some embodiments, the first control circuit of the switching control circuit may further comprise a first time-to-digital converter (TDC), wherein the first TDC is configured to determine an illumination signal offset between the duration of the illumination source enabled signal and the target duration of the illumination source enabled signal.

In some embodiments, the first control circuit may further comprise a first proportional-integral-derivative controller configured to generate the duration target code based on the illumination signal offset.

In some embodiments, the second control circuit further comprises a second time-to-digital converter (TDC) configured to determine a selection signal offset, wherein the selection signal offset represents a time difference between the target overlap and an overlap of a selection switch status signal and a main switch status signal. In some embodiments, the selection switch status signal may be based at least in part on the selection switch enable signal. In some embodiments, the main switch status signal is based at least in part on the main switch enable signal.

In some embodiments, the second control circuit may further comprise a second proportional-integral-derivative controller configured to generate an overlap target code based on the selection signal offset.

In some embodiments, the second control circuit may further comprise an illumination signal off programmable delay line configured to generate an illumination off signal based on the overlap target code and the target overlap.

In some embodiments, the second control circuit may de-asserts the selection switch enable signal based on the illumination off signal.

In some embodiments, the electronic system may further comprise a plurality of selection switches, and a plurality of switching control circuits, each switching control circuit associated with a selection switch.

In some embodiments, the second control circuit may be a cascade of the first control circuit, such that adjustments to the duration target code do not affect the overlap target code and adjustments to the overlap target code do not affect the duration target code.

An example method for generating a pulsed illumination signal is further provided. In some embodiments, the example method may comprise receiving, at a pulsed signal generator, a pulsed electronic signal, and receiving, from an illumination source at the pulsed signal generator, an illumination source enabled signal indicating a status of the illumination source. The method may further comprise generating, at a first control circuit, a duration target code indicative of a comparison between a duration of the illumination source enabled signal and a target duration of the illumination source enabled signal based at least in part on the illumination source enabled signal. The method may further comprise receiving, at a second control circuit, the duration target code. In some embodiments, the method may comprise determining, at the second control circuit, a main switch enable signal configured to activate a main switch, and determining, at the second control circuit, a selection switch enable signal based at least in part on the duration target code and a target overlap with the main switch enable signal. In some embodiments, the selection switch enable signal may be configured to activate a selection switch, and the selection switch may enable current flow to the illumination source. In some embodiments, the method may comprise generating a pulsed illumination signal based at least in part on the selection switch enable signal.

In some embodiments, the method may further comprise determining, at a first time-to-digital converter (TDC) of the first control circuit, an illumination signal offset between the duration of the illumination source enabled signal and the target duration of the illumination source enabled signal.

In some embodiments, the method may further comprising receiving, at a first proportional-integral-derivative controller, the illumination signal offset; and generating the duration target code based on the illumination signal offset.

In some embodiments, the method may further comprise receiving, at a second time-to-digital converter of the second control circuit, a selection switch status signal and a main switch status signal, wherein the selection switch status signal is based at least in part on the selection switch enable signal, and wherein the main switch status signal is based at least in part on the main switch enable signal. In some embodiments, the method may further comprise determining a selection signal offset based at least in part on a time difference between the target overlap and an overlap of the selection switch status signal and the main switch status signal.

In some embodiments, the method may further comprise receiving, at a second proportional-integral-derivative controller of the second control circuit, the selection signal offset, and generating an overlap target code based at least in part on the selection signal offset.

In some embodiments, the method may further comprise receiving, at an illumination signal off programmable delay line of the second control circuit, the overlap target code and the target overlap, and generating an illumination off signal based at least in part on the overlap target code and the target overlap.

In some embodiments, the method may further comprise de-asserting the selection switch enable signal based at least in part on the illumination off signal.

In some embodiments, the pulsed signal generator may further comprise a plurality of selection switches, and a plurality of switching control circuits, each switching control circuit associated with a selection switch.

In some embodiments, the second control circuit may be a cascade of the first control circuit, such that adjustments to the duration target code do not affect the overlap target code and adjustments to the overlap target code do not affect the duration target code.

An example light detection and ranging (LIDAR) system is further provided. In some embodiments, the example LIDAR system may comprising a controller, a pulse emitting circuit electrically connected to the controller and an illumination source, wherein the illumination source is configured to generate a light output based at least in part on an illumination source enabled signal. In some embodiments, the example LIDAR system may comprise a pulsed signal generator. The pulsed signal generator may comprise a main switch electrically connected to the pulse emitting circuit, a selection switch electrically connected to the main switch, and a switching control circuit. In some embodiments, the selection switch may control a current flow to the illumination source. In some embodiments, the switching control circuit may comprise a first control circuit and a second control circuit. In some embodiments, the first control circuit may receive the illumination source enabled signal indicating a status of the illumination source, and generate a duration target code indicative of a comparison between a duration of the illumination source enabled signal and a target duration of the illumination source enabled signal. In some embodiments, the switching control circuit may comprise a second control circuit, wherein the second control circuit may receive the duration target code, and determine a main switch enable signal configured to activate the main switch and a selection switch enable signal configured to activate the selection switch, based at least in part on the duration target code and a target overlap. In some embodiments, the example LIDAR system may further comprise an emitted pulse receiver electrically connected to the controller and configured to receive a reflection of the light output off an object. In some embodiments, the controller may be configured to determine a distance of the object based on the reflection of the light output.

In some embodiments, the pulsed signal generator may further comprise a plurality of selection switches, and a plurality of switching control circuits, each switching control circuit associated with a selection switch.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates a block diagram of an example electronic system including a pulsed signal generator in accordance with one or more embodiments of the present disclosure.

FIG. 2 depicts an example current flow through an example four channel pulsed illumination generator circuit in accordance with an example embodiment of the present disclosure.

FIG. 3 illustrates a circuit level diagram of an example pulse emitting circuit, main switch circuitry, selection switch circuitry, and illumination source circuitry in accordance with an example embodiment of the present disclosure.

FIG. 4 depicts a block diagram of an example switching control circuit in accordance with an example embodiment of the present disclosure.

FIG. 5 illustrates a circuit level diagram of an example first control circuit of an example switching control circuit in accordance with an example embodiment of the present disclosure.

FIG. 6 illustrates a circuit level diagram of an example second control circuit of an example switching control circuit in accordance with an example embodiment of the present disclosure.

FIG. 7 depicts a circuit level diagram of an example electronic system including a pulsed signal generator for a multi-channel LIDAR application in accordance with one or more embodiments of the present disclosure.

FIG. 8 depicts an example signal diagram of an example pulsed signal generator for a multi-channel LIDAR application in accordance with one or more embodiments of the present disclosure.

FIG. 9 depicts an example flow chart of a method for generating a pulsed illumination signal in accordance with one or more embodiments of the present disclosure.

FIG. 10 depicts an example block diagram for an example LIDAR application including a pulsed signal generator in accordance with one or more embodiments of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

As described herein, the term “high” when referring to voltages indicates the identified voltage is above a certain minimum voltage threshold for the electronic device, generally between 1.8 volts and 3.6 volts. Similarly, the term “low” when referring to voltages indicates the identified voltage is below a certain voltage threshold for the electronic device, generally at or near 0 volts.

Various example embodiments address technical problems associated with generating electronic pulse signals to power a laser diode configured to generate a pulsed illumination signal, particularly in a multi-channel LIDAR applications. In general, multi-channel LIDAR applications include multiple laser diodes used to generate very short (approximately 1 nanosecond), high current (up to 40 amps each) pulses. These pulses are directed by an optic system, typically including two micro-electromechanical (MEMS) mirrors for horizontal and vertical scanning, toward a target environment. The system further includes a receiver (e.g., a Single-Photon Avalanche Diode) positioned to receive the pulses as they reflect off various obstacles in the environment. The reception of the pulses enables the system to measure the time-of-flight (ToF) of the pulse and determine obstacle distances, enabling the system to reconstruct a 3D image of the target environment.

In some embodiments, in order to reduce the required resonance peak current generated by a pulse emitting circuit (e.g., LC circuit), pulses are generated by each of the laser diodes in sequence, instead of simultaneously. The sequential activation of the multiple laser diodes may be accomplished by a series of selection switches. In some embodiments, a main switch may control the activation and deactivation of the resonance period of the signal generated by the pulse emitting circuit. Once the resonance period begins and the current through the switching mechanism has ramped up, the main switch “transfers” the current from the main switch to each of the selection switches during the time of peak resonance current of the signal generated by the pulse emitting circuit. In between activation of each of the selection circuits, the current is switched back to the main switch. Typically, Gallium Nitride (GaN) switches are used to drive each of these laser diodes due to the ability of the GaN switches to quickly turn on and turn off, thus supporting higher frequency, higher precision switching.

In order to guarantee a continuous path for the resonant current, a certain amount of overlap time must be guaranteed between when the main switch is activated and when each of the selection switches are deactivated. However, the overlap pulse at the end of the selection switch pulse must be reduced to a minimum to speed-up the laser turn-off. The quicker the laser turn-off the more precise the pulsed illumination signal, and the more accurate the mapping of the target environment based on the received reflections. In order to precisely control the amount of overlap, the system must account for response delays. For example, a delay from the time the switch driver sends a command to switch on or off the main or selection switches and the time the switch actually switches off. In addition, a delay may occur between the instance at which the switch switches on/off and the instance at which the laser pulse is enabled/disabled. To further complicate things, the delays within the system may be dependent on temperature.

One approach that has been used to control the gate delays across different operating temperatures is to compensate for timing variation by inserting programmable delay chains on the path which provides signals to the illumination source circuitry. In such an embodiment, each device is calibrated at different temperatures. The results for each temperature may then be stored in non-volatile memory and the delay chain may be programmed for each temperature during operation based on the table stored in non-volatile memory. Drawbacks of this solution include an increase in the overall time and cost of calibration to test each system at various temperatures. In addition, the calibration table may need to be updated over time due to the aging of the system and system components.

The various example embodiments described herein utilize various techniques to provide a high precision and PVT invariant synchronization between the main switch and the plurality of selection switches in a multi-channel LIDAR application.

For example, in some embodiments, to control the synchronization of the main switch and each of the selections switches, two digital control circuits are implemented within a switching control circuit of the pulsed signal generator. A laser pulse duration digital control circuit and a selection switch activation digital control circuit.

In general, the laser pulse duration digital control circuit compares the pulse width of a pulsed illumination signal of a connected laser diode and determines any adjustment that may be made to align the pulse width duration of the pulsed illumination signal with a target pulse width duration. The laser pulse duration digital control circuit may detect the time difference between the time the laser diode turns off and the time the laser diode was expected to turn off based on the target pulse width duration. The laser diode off signal may then be adjusted to align the time the laser switches off with the expected laser off time. The result of the laser pulse duration digital control circuit is a duration target code, indicating the delay required to obtain the target pulse width of the pulsed illumination signal.

A selection switch activation digital control circuit, may monitor the gate voltage of the main switch and a selection switch, for example, to detect and adjust the time difference between the instance in which the main switch is enabled and the instance in which the selection switch is disabled. In practice, the smaller the overlap between deactivating the selection switch and activating the main switch, the faster the laser diode connected to the selection switch may turn off. Further, the faster the laser diode can turn off, the more accurate the measurements based on the reflection of the pulsed illumination signal.

In addition, because a PVT invariant reference clock is used in the determination of each of the duration target code, and the main switch and selection switch enable and disable signals, the pulsed signal generator may be PVT invariant. Alleviating the need for complex calibrations to determine the operation of the circuit components across various temperatures and process voltages.

As a result of the herein described example embodiments and in some examples, the effectiveness and accuracy of a pulsed signal generator on a multi-channel LIDAR system may be greatly improved. In addition, due to the PVT invariance of the pulsed signal generator, the initialization of the circuit may be greatly simplified.

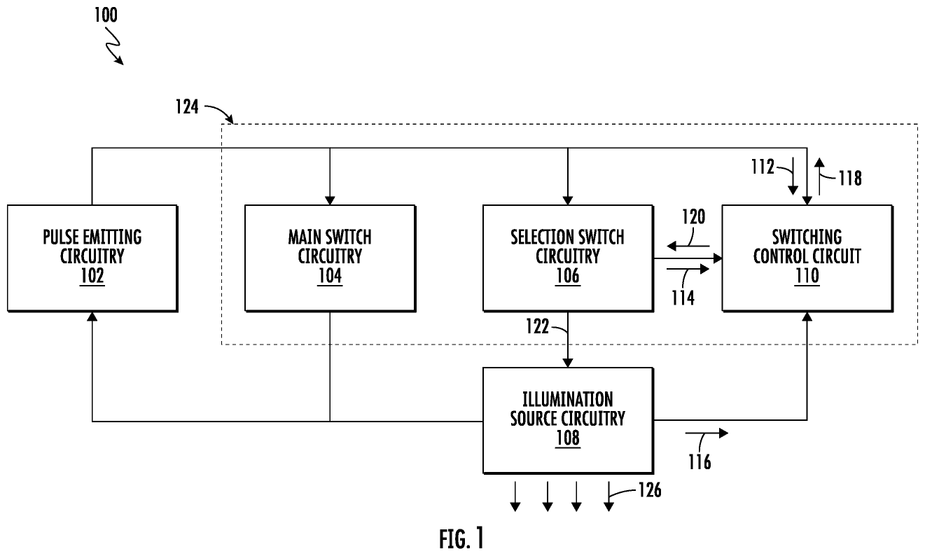

Referring now to FIG. 1, an example block diagram of an example pulsed illumination generator circuit 100 is provided. As depicted in FIG. 1, the example pulsed illumination generator circuit 100 includes a pulse emitting circuit 102 electrically connected to a pulsed signal generator 124 and illumination source circuitry 108 in series. As further depicted in FIG. 1, the pulsed signal generator 124 includes main switch circuitry 104 electrically connected in parallel with selection switch circuitry 106. The pulsed signal generator 124 further comprises a switching control circuit 110 configured to receive status signals from the electrically connected main switch circuitry 104 (e.g., main switch status signal 112) and the electrically connected illumination source circuitry 108 (e.g., illumination source enabled signal 116). As further depicted in FIG. 1, the switching control circuit 110 is further configured to generate a main switch enable signal 118 transmitted to the main switch circuitry 104, and a selection switch enable signal 120 transmitted to the selection switch circuitry 106. Upon receipt of the selection switch enable signal 120, the selection switch circuitry 106 may transmit a pulsed illumination signal 122 to the illumination source circuitry 108, causing the illumination source circuitry 108 to generate a pulsed illumination output 126. The selection switch circuitry 106 may further provide a selection switch status signal 114, indicating the status of the selection switch circuitry 106.

As depicted in FIG. 1, the example pulsed illumination generator circuit 100 includes a pulse emitting circuit 102. A pulse emitting circuit 102 may be any resonant circuit comprising hardware, software, firmware, or combination thereof configured to generate an oscillating current at a particular resonant frequency. In some embodiments, the pulse emitting circuit 102 may comprise an LC circuit or tank circuit. In some embodiments, such as a multi-channel LIDAR application, the current generated by a pulse emitting circuit 102 may be utilized to drive one or more illumination sources, for example, laser diodes included in example illumination source circuitry 108.

As further depicted in FIG. 1, the pulsed illumination generator circuit 100 includes a pulsed signal generator 124 connected in series with the pulse emitting circuit 102 and the illumination source circuitry 108. The depicted pulsed signal generator 124 includes main switch circuitry 104 electrically connected in parallel with the selection switch circuitry 106. As depicted, the main switch circuitry 104 may comprise hardware, firmware, software, or any combination thereof, configured to switch electric current provided by the pulse emitting circuit 102 through the main switch circuitry 104. For example, in some embodiments, the main switch circuitry 104 may comprise a metal-oxide-semiconductor field effect transistor (MOSFET), a bipolar junction transistor (BJT), or another transistor/switching device and accompanying circuitry. In some embodiments, the main switch circuitry 104 may comprise a Galium Nitride (GaN) switch enabling faster switching speeds, higher operating frequencies, and high-power applications.

The depicted pulsed signal generator 124 further includes selection switch circuitry 106 electrically connected in parallel with the main switch circuitry 104. The selection switch circuitry 106 may comprise hardware, firmware, software, or any combination thereof, configured to switch electric current provided by the pulse emitting circuit 102 through the selection switch circuitry 106. For example, in some embodiments, the selection switch circuitry 106 may comprise a MOSFET, a bipolar junction transistor BJT, or another transistor/switching device and accompanying circuitry. In some embodiments, the selection switch circuitry 106 may comprise a GaN switch enabling faster switching speeds, higher operating frequencies, and high-power applications.

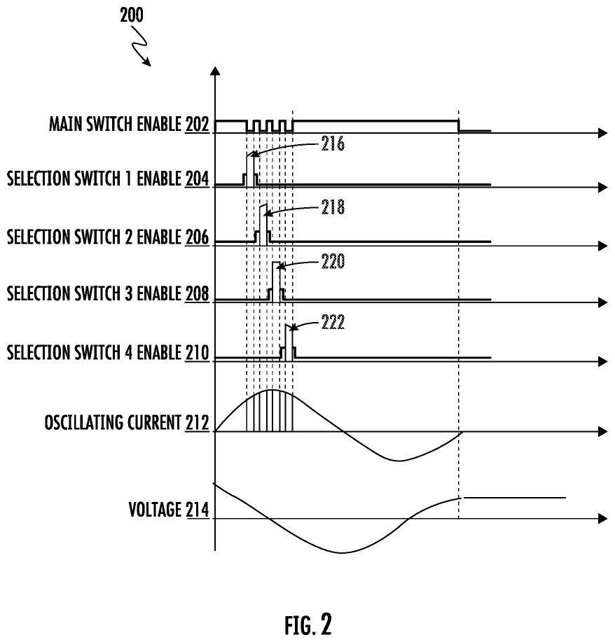

In general, the main switch circuitry 104 and the selection switch circuitry 106 work in coordination to control the flow of current generated by the pulse emitting circuit 102 through the pulsed signal generator 124. Referring now to FIG. 2 the graph 200 depicts an example current flow through an example four channel pulsed illumination generator circuit 100 comprising a pulsed signal generator 124. As depicted in FIG. 2, the pulse emitting circuit 102 generates an oscillating current 212 having a voltage 214. In order to obtain accurate distance measurements, the pulsed illumination generator circuit 100 may wait until the oscillating current 212 has reached a certain threshold current before generating a pulsed illumination output 126.

As depicted in FIG. 2, in an instance in which the main switch circuitry 104 is enabled (as depicted by the main switch enable 202), current flows through the main switch circuitry 104. Thus, the main switch enable 202 remains high until the oscillating current 212 reaches a certain minimum threshold current. In an instance in which the oscillating current 212 reaches a certain minimum threshold current, the main switch enable 202 is disabled and the selection switch one enable 204 is enabled, allowing the flow of current through the selection switch circuitry 106 (e.g., switch one current 216) and the illumination source circuitry 108, generating a pulsed illumination output 126.

As shown in FIG. 2, in a multi-channel LIDAR application, a plurality of channels are enabled in sequence by switching the oscillating current 212 from the main switch circuitry 104 (e.g., main switch enable 202 is enabled), to the selection switch circuitry 106 (e.g., selection switch one enable 204 is enabled) and associated illumination source, back to the main switch circuitry 104, to the next selection switch in the selection switch circuitry 106 (e.g., selection switch two enable 206 is enabled) and associated illumination source, and so on. Thus, selection switch one enable 204, selection switch two enable 206, selection switch three enable 208, and selection switch four enable 210 are all asserted in a single oscillation of the oscillating current 212, enabling current to flow through each of the selection switches in the selection switch circuitry 106 as evidenced by switch one current 216, switch two current 218, switch three current 220, and switch four current 222, thus producing a pulsed illumination output 126 out of an illumination source associated with each of the switches.

In some multi-channel LIDAR applications, a pulsed illumination generator circuit may support a variable number of channels. For example, given a specific hardware configuration, a pulsed illumination generator circuit may support a maximum number of channels (e.g., four transmission channels). However, during operation, the multi-channel LIDAR application may vary the number of enabled transmission channels. For example, one transmission channel may be enabled in an instance in which objects are detected at short distances and all four transmission channels may be enabled in which objects are detected at longer distances. even a different number according to the position in the scene. In such an instance, the number of transmission channels enabled during a single oscillation of the oscillating current 212 may vary during operation. In such an instance, the timing may be updated to support a variable number of transmission channels.

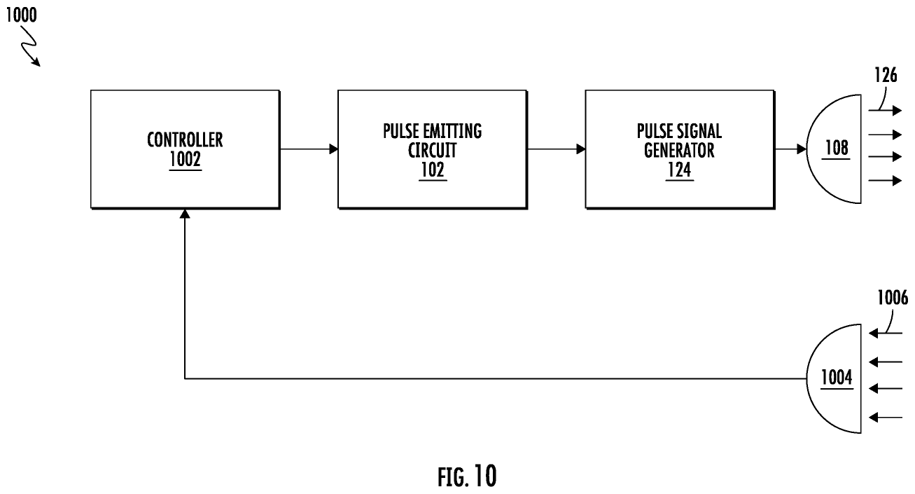

Returning now to FIG. 1, the example pulsed illumination generator circuit 100 further comprises illumination source circuitry 108. Illumination source circuitry 108 may include an illumination source and associated circuitry configured to generate a pulsed illumination output 126 upon receipt of a pulsed illumination signal 122. An illumination source may comprise any light source, such as a laser diode, a light-emitting diode, or other similar source configured to output light. In some embodiments, an illumination source may comprise a semiconductor laser diode, for example, a vertical cavity surface emitting laser (VCSEL) and/or an edge emitting laser diode. In general, an illumination source may output a coherent light beam upon receipt of a current, such as the oscillating current produced by the pulse emitting circuit 102. In a LIDAR application, the distance of objects in an environment may be measured by generating a pulsed illumination output 126, receiving a reflected pulsed illumination (e.g., reflected pulsed illumination 1006 as shown in FIG. 10), and determining the time-of-flight of the pulsed illumination output 126.

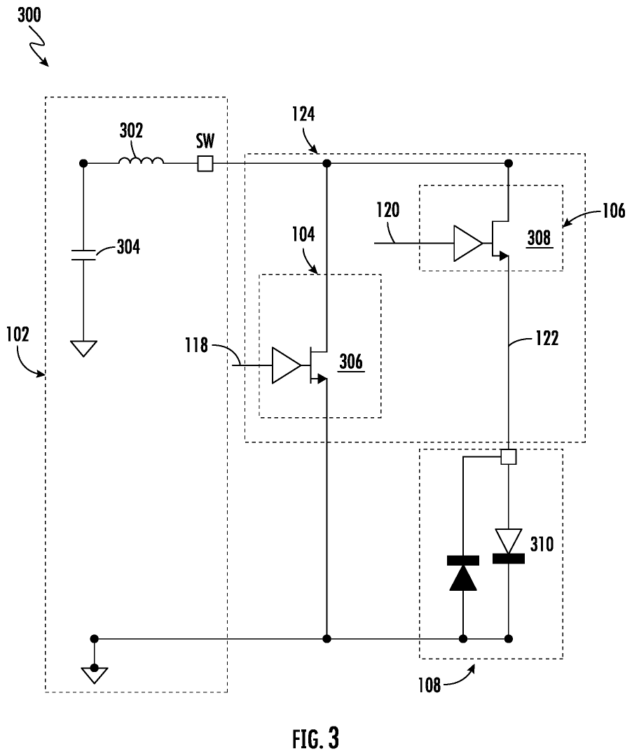

As further depicted in FIG. 1, the example pulsed signal generator 124 includes a switching control circuit 110 configured to receive electrical data from the main switch circuitry 104 (e.g., main switch status signal 112), the selection switch circuitry 106 (e.g., selection switch status signal 114), and the illumination source circuitry 108 (e.g., illumination source enabled signal 116) to generate a main switch enable signal 118 and a selection switch enable signal 120. A pulsed signal generator 124 may be any hardware, firmware, software, or combination thereof configured to determine the switching sequence of the main switch circuitry 104 and one or more switches comprising the selection switch circuitry 106 of the pulsed illumination generator circuit 100 and as further described in FIG. 3-FIG. 8.

As further depicted in FIG. 1, the example switching control circuit 110 may exchange electrical signals with the main switch circuitry 104. In some embodiments, the main switch circuitry 104 may generate and transmit a main switch status signal 112. The main switch status signal 112 may be any signal indicating the status of the main switch circuitry 104. For example, the main switch status signal 112 may indicate whether the main switch within the main switch circuitry 104 is open, preventing current from passing through the main switch circuitry 104, or closed, enabling current to pass through the main switch circuitry 104. In some embodiments, the main switch status signal 112 may be generated based at least in part on the voltage between the gate and source of the switching device (e.g., MOSFET, BJT) comprising the main switch circuitry 104. For example, the main switch status signal 112 may be generated by a comparator monitoring the gate-source voltage of the switching device. Similarly, switch status signals may be generated and transmitted for each of the switching devices in the selection switch circuitry 106.

As further depicted in FIG. 1, the switching control circuit may generate a main switch enable signal 118 and transmit the main switch enable signal 118 to the main switch circuitry 104. The main switch enable signal 118 may be any signal or series of signals altering the state of the main switch circuitry 104. For example, in some embodiments, the main switch enable signal 118 may cause a voltage to be supplied to the gate of the switching device of the main switch circuitry 104. In some embodiments, in an instance in which the main switch enable signal 118 is high, the switching device of the main switch circuitry 104 may be enabled, allowing the flow of current through the main switch circuitry 104, and in an instance in which the main switch enable signal 118 is low, the switching device of the main switch circuitry 104 may be disabled, preventing the flow of current through the main switch circuitry 104.

As further depicted in FIG. 1, the example switching control circuit 110 may receive a selection switch status signal 114 from the selection switch circuitry 106. The selection switch status signal 114 may be any signal indicating the status of the selection switch circuitry 106. For example, the selection switch status signal 114 may indicate whether a selection switch within the selection switch circuitry 106 is open, preventing current from passing through the particular switch, or closed, enabling current to pass through the particular switch and corresponding illumination source. In some embodiments, the selection switch status signal 114 may be generated based at least in part on the voltage between the gate and source of the switching device (e.g., MOSFET, BJT) comprising the selection switch circuitry 106. For example, the selection switch status signal 114 may be generated by a comparator monitoring the gate-source voltage of the switching device. Similarly, switch status signals may be generated and transmitted for each of the switching devices in the selection switch circuitry 106.

As further depicted in FIG. 1, the example switching control circuit 110 may receive an illumination source enabled signal 116. The illumination source enabled signal 116 may be any signal indicating the status of one or more illumination sources of the illumination source circuitry 108. For example, the illumination source enabled signal 116 may indicate whether the illumination source within the illumination source circuitry 108 is on, producing pulsed illumination output 126, or off and not producing any pulsed illumination output 126. In some embodiments, the illumination source enabled signal 116 may be generated based at least in part on the voltage at the anode of the light illumination source (e.g., laser diode). For example, the illumination source enabled signal 116 may be generated by a comparator monitoring the anode voltage of the laser diode.

As further depicted in FIG. 1, the switching control circuit 110 may generate and transmit one or more selection switch enable signals 120 to the selection switch circuitry 106. The selection switch enable signal 120 may be any signal or series of signals altering the state of one or more of the selection switches comprising the selection switch circuitry 106. For example, in some embodiments, the selection switch enable signal 120 may cause a voltage to be supplied to the gate of a switching device associated with a channel in the selection switch circuitry 106. In some embodiments, in an instance in which the selection switch enable signal 120 is high for a particular channel switching device, the switching device may be enabled, allowing the flow of current through the channel of the selection switch circuitry (as depicted in FIG. 2) and causing the associated illumination source to generate pulsed illumination output 126. In an instance in which the selection switch enable signal 120 is low for a particular channel switching device, the switching device may be disabled, preventing the flow of current through the channel of the selection switch circuitry, preventing the illumination source from generating pulsed illumination output 126.

Referring now to FIG. 3, an example embodiment of a pulsed illumination generator circuit 300 is provided. As depicted in FIG. 3, the example pulsed illumination generator circuit 300 includes a pulse emitting circuit 102 configured to output an oscillating current. The depicted pulse emitting circuit 102 includes an LC circuit or tank circuit, utilizing a capacitor 304 and an inductor 302 to generate an oscillating current.

The pulse emitting circuit 102 of FIG. 3 is electrically connected to the input of a pulsed signal generator 124 which is subsequently electrically connected to the illumination source circuitry 108 at one output before returning to the pulse emitting circuit 102, and electrically connected directly back to the pulse emitting circuit 102 at another output.

As further depicted in FIG. 3, the pulsed signal generator 124 comprises main switch circuitry 104 and selection switch circuitry 106. The main switch circuitry 104 of the example pulsed illumination generator circuit 300 further comprises a main switch switching device 306 configured to receive a main switch enable signal 118 to control the flow of current through the main switch circuitry 104. Although depicted as a MOSFET in FIG. 3, as described in relation to FIG. 1, the main switch switching device 306 may be any MOSFET, bipolar junction transistor BJT, or other transistor/switching device configured to control the flow of current through the main switch circuitry 104 and back to the pulse emitting circuit 102 based at least in part on the main switch enable signal 118.

As further depicted in FIG. 3, the selection switch circuitry 106 of the example pulsed illumination generator circuit 300 comprises selection switch circuitry 106 further comprising a selection switch switching device 308. Although depicted as a MOSFET in FIG. 3, as described in relation to FIG. 1, the selection switch switching device 308 may be any MOSFET, bipolar junction transistor BJT, or other transistor/switching device configured to control the flow of current through the selection switch circuitry 106 and associated illumination source circuitry 108, based at least in part on the selection switch enable signal 120.

As further depicted in FIG. 3, the example illumination source circuitry 108 includes a laser diode 310 configured to receive a pulsed illumination signal 122 from the selection switch switching device 308 and generate a pulsed illumination output 126. A laser diode 310 may be any semiconductor device configured to generate coherent light. As depicted in FIG. 3, in an instance in which the associated selection switch switching device 308 enables the flow of current through the illumination source circuitry 108, the laser diode 310 may be stimulated and illuminate, generating a pulsed illumination output 126 comprising a coherent laser beam. As described in relation to FIG. 2, in some embodiments, the oscillating current from the pulse emitting circuit 102 may be transferred between the main switch circuitry 104 and the selection switch circuitry 106 and associated illumination source circuitry 108, thus generating high precision, short and high current pulsed illumination output 126.

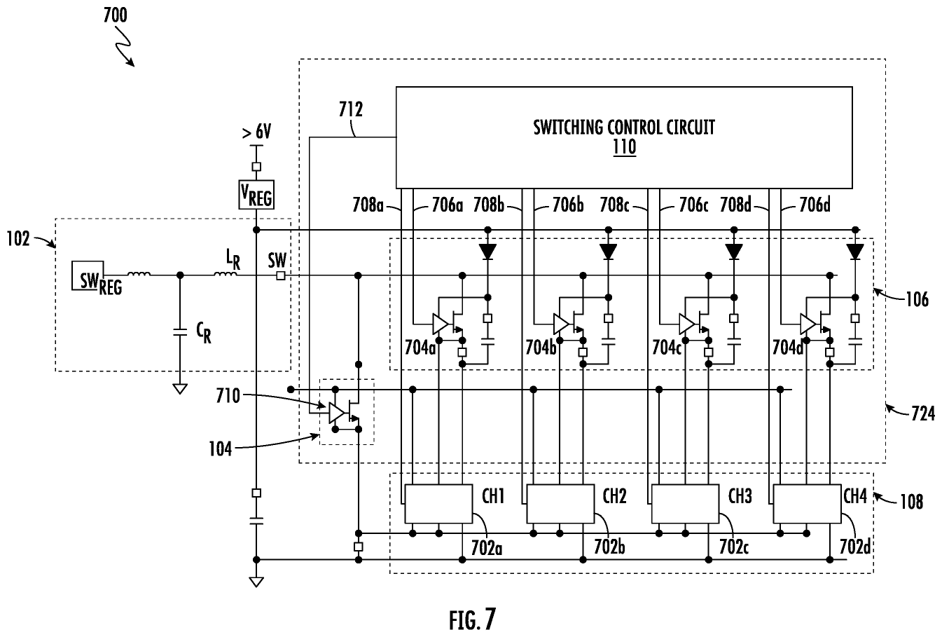

Although depicted as a single channel pulsed illumination generator circuit 300 in FIG. 3, the example pulsed illumination generator circuit 300 may comprise a plurality of channels comprising a plurality of selection switch switching devices 308 and associated laser diodes 310, for example, as depicted in FIG. 7.

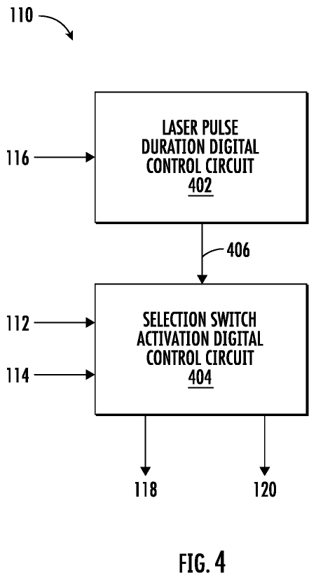

Referring now to FIG. 4, an example switching control circuit 110 of a pulsed signal generator in a pulsed illumination generator circuit is provided. As depicted in FIG. 4, the example switching control circuit 110 includes a laser pulse duration digital control circuit 402 electrically connected to a selection switch activation digital control circuit 404. The example laser pulse duration digital control circuit 402 is configured to receive an illumination source enabled signal 116 and generate a duration target code 406. The selection switch activation digital control circuit 404 is configured to receive the duration target code 406 from the laser pulse duration digital control circuit 402, the main switch status signal 112, and selection switch status signal 114 and generate a main switch enable signal 118 and a selection switch enable signal 120.

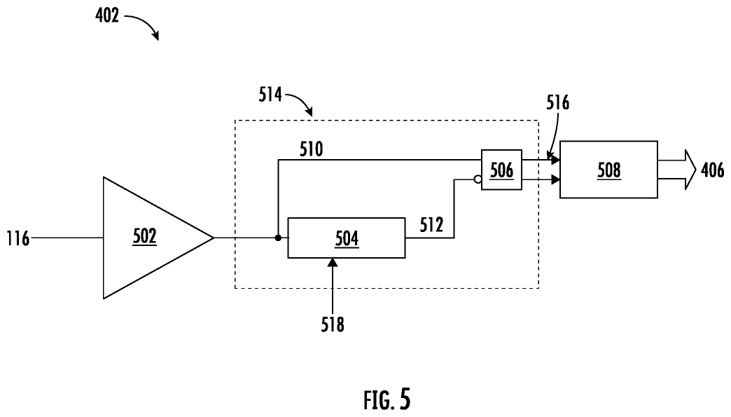

As depicted in FIG. 4, the example switching control circuit 110 includes a laser pulse duration digital control circuit 402 (e.g., first control circuit). A laser pulse duration digital control circuit 402 may be any hardware, firmware, software, or combination thereof configured to receive an illumination source enabled signal 116 and output a duration target code 406 indicative of the pulse width of a pulsed illumination output (e.g., pulsed illumination output 126). A laser pulse duration digital control circuit is described in more detail in relation to FIG. 5. In some embodiments, a target pulse width may be indicated. A target pulse width may be indicated by an external user, may be determined based on a calibration, may be determined based on the number of channels and the oscillation frequency of the pulse emitting circuit 102, or by other similar means. In some embodiments, the target pulse width may be variable during operation and may be updated based on the operation parameters of the utilizing system, the surrounding environment, and/or other factors. In some embodiments, the target pulse width may be fixed at start-up based on an input or configuration parameter.

The target pulse width (e.g., target duration) may be any data construct or variable, configured to indicate the duration of the generated pulsed illumination output 126. In some applications, including LIDAR applications, the accuracy of measurements may be dependent on the duration of the generated pulsed illumination output 126. For example, measured distances and other information about the surrounding environment may be affected by a change and/or variation in the pulse width of a generated pulsed illumination output 126. The laser pulse duration digital control circuit 402 may receive the illumination source enabled signal 116 and compare the pulse width of the illumination source (e.g., laser diode 310) with the target pulse width. The duration target code 406 may be updated based on the comparison.

As further depicted in FIG. 4, the laser pulse duration digital control circuit 402 may generate a duration target code 406. A duration target code 406 may be any data construct, number, sequence of numbers, or similar device indicating the pulse width duration of a pulsed illumination output 126. For example, in some embodiments, the duration target code 406 may represent a correction code derived from the difference between the measured pulse duration (e.g., the duration of the illumination source enabled signal 116) and the target duration (e.g., the target pulse width 518 as further described in relation to FIG. 5). If the two are equal, no modification on the duration target code 406 is needed, otherwise the duration target code 406 is updated accordingly. In such an embodiment, time may be measure in seconds, nanoseconds, clock cycles, or any other similar measurement device.

As further depicted in FIG. 4, the example switching control circuit 110 includes a selection switch activation digital control circuit 404 (e.g., second control circuit). The selection switch activation digital control circuit 404 may be any hardware, firmware, software, or combination thereof configured to generate a main switch enable signal 118, and a selection switch enable signal 120, such that the synchronization of the main switch switching device (e.g., main switch switching device 306) and the selection switch switching device(s) (e.g., selection switch switching device 308) are synchronized.

In order to guarantee a continuous path for the oscillating current generated by the pulse emitting circuit 102, a certain amount of overlap time must be guaranteed between the main switch switching device and each of the selection switch switching device activations. In particular, the overlap at the end of the pulse must be reduced to a minimum to increase the speed of the illumination device turn off. Increasing the speed of the illumination device turn off may improve the accuracy of measurements based on the generated pulsed illumination output. As such, the selection switch activation digital control circuit 404 may generate the main switch enable signal 118 and the one or more selection switch enable signals 120 such that a target overlap is obtained.

The target overlap may be any data construct or variable, configured to indicate the duration of time in which a selection switch switching device is still enabled once the main switch switching device is enabled. For example, in an instance in which an illumination source is enabled by a selection switch switching device, the main switch switching device may be enabled for a period of time before the selection switch switching device is disabled. Such a period of time is referred to as an overlap. The target overlap is the desired amount of time the main switch switching device may be enabled before the selection switch switching device is disabled. The desired amount of time may be indicated in seconds, microseconds, nanoseconds, clock cycles, or any other similar measurement device. For example, a target overlap may be 1 nanosecond, or, as another example, four clock cycles. A target overlap may be indicated by an external user, may be determined based on a calibration, may be determined based on the number of channels and the oscillation frequency of the pulse emitting circuit 102, or by other similar means. In some embodiments, the target overlap may be variable during operation and may be updated based on the operation parameters of the utilizing system, the surrounding environment, and/or other factors. In some embodiments, the target overlap may be fixed at start-up based on an input or configuration parameter.

Referring now to FIG. 5, an example embodiment of a laser pulse duration digital control circuit 402 is provided. As depicted in FIG. 5, the laser pulse duration digital control circuit 402 includes a pulse duration operational amplifier 502 configured to receive an illumination source enabled signal 116 and output an amplified illumination source enabled signal 510. The depicted laser pulse duration digital control circuit 402 further includes a pulse width time-to-digital converter (TDC) 514 electrically connected to the pulse duration operational amplifier 502 and configured to receive the amplified illumination source enabled signal 510 and a target pulse width 518 and determine an illumination signal offset 516. A pulse width proportional-integral-derivative (PID) is electrically connected to the pulse width TDC 514 and configured to receive the illumination signal offset 516 and generate a duration target code 406 based at least in part on the illumination signal offset 516. As further depicted in FIG. 5, the pulse width TDC 514 includes a pulse width programmable delay line 504 configured to receive the target pulse width 518 and compare the amplified illumination source enabled signal 510 with the inverse of an illumination target off signal 512, generated by the pulse width programmable delay line 504, at a pulse width phase detector 506, to produce the illumination signal offset 516.

As depicted in FIG. 5, the example laser pulse duration digital control circuit 402 includes a pulse duration operational amplifier 502. A pulse duration operational amplifier 502 may be any electronic component configured to receive an input voltage and generate an amplified output voltage proportional to the received input voltage. As shown in FIG. 5, the pulse duration operational amplifier 502 receives the illumination source enabled signal 116 and generates the amplified illumination source enabled signal 510. The amplified illumination source enabled signal 510 is transmitted to the pulse width TDC 514 for further analysis as described herein. In some embodiments, the pulse duration operational amplifier 502 may comprise a comparator, which may be configured to generate the amplified illumination source enabled signal 510 according to a voltage level of the illumination source enabled signal 116 signal (e.g., above a certain first threshold and below a certain second threshold).

As further depicted in FIG. 5, the laser pulse duration digital control circuit 402 includes a pulse width TDC 514. A pulse width TDC 514 may be any hardware, firmware, software, or combination thereof configured to receive a signal having a defined pulse width and a target pulse width 518 and determine difference between the target pulse width 518 and the defined pulse width. In some embodiments, the pulse width TDC 514 may comprise process voltage, and temperature (PVT) invariant components, for example a PVT invariant pulse width programmable delay line 504. A pulse width TDC 514 comprising PVT invariant components may be robust to changes in temperature and process voltage in determining a duration target code 406. As depicted in FIG. 5, the TDC implementation represents one specific embodiment, however, any TDC implementation which relies on a PVT-invariant delay line can be used to generate the illumination signal offset 516.

As further depicted in FIG. 5, the example pulse width TDC 514 includes a pulse width phase detector 506. A pulse width phase detector 506 may be any electronic device configured to measure the phase difference between two input signals and produce an output that is proportional to the phase difference between the two signals. As shown in FIG. 5, the first input to the pulse width phase detector 506 may be the amplified illumination source enabled signal 510. The second input to the pulse width phase detector is an inverse of the illumination target off signal 512. In some embodiments, the amplified illumination source enabled signal 510 is used with both polarities: one polarity to capture the laser turning-on, which is then delayed to generate the illumination target off signal 512, and one polarity to capture the laser turning-off, which is provided to the phase detector 506. The polarity of the amplified illumination source enabled signal 510 and illumination target off signal 512 at the input of the phase detector 506 may then be chosen in such a way that the phase detector 506 may quantify the difference between the actual pulse duration (information included in amplified illumination source enabled signal 510) and the expected one (information included in illumination target off signal 512). In such embodiments, the amplified illumination source enabled signal 510 may be inverted at the pulse width phase detector 506 and the illumination target off signal 512 may be compared without inversion.

As further depicted in FIG. 5, the illumination target off signal 512 is generated by transmitting the amplified illumination source enabled signal 510 through a pulse width programmable delay line 504 (e.g., first programmable delay line). A pulse width programmable delay line 504 may be any hardware, firmware, software, or any combination thereof device configured to receive a signal (e.g., amplified illumination source enabled signal 510) and a delay (e.g., target pulse width 518) and delay the signal by the delay. Thus, the illumination target off signal 512 may comprise the amplified illumination source enabled signal 510 delayed by the target pulse width 518. Thus, the illumination target off signal 512 may be asserted as the amplified illumination source enabled signal 510 is de-asserted. By inverting the illumination target off signal 512 at the pulse width phase detector 506 the difference between the pulse width of the amplified illumination source enabled signal 510 and the target pulse width 518 may be measured. The illumination signal offset 516 may represent the difference between the pulse width of the amplified illumination source enabled signal 510 and the target pulse width 518.

As further depicted in FIG. 5, the example laser pulse duration digital control circuit 402 includes a pulse width PID 508. A pulse width PID 508 may be any device comprising hardware, firmware, software, or any combination thereof configured to generate a signal based on an error between a desired signal and the actual measured value. As shown in FIG. 5, the pulse width PID 508 may generate a duration target code 406 based on the illumination signal offset 516 representing the difference between the pulse width duration of the illumination source enabled signal 116 and the target pulse width 518.

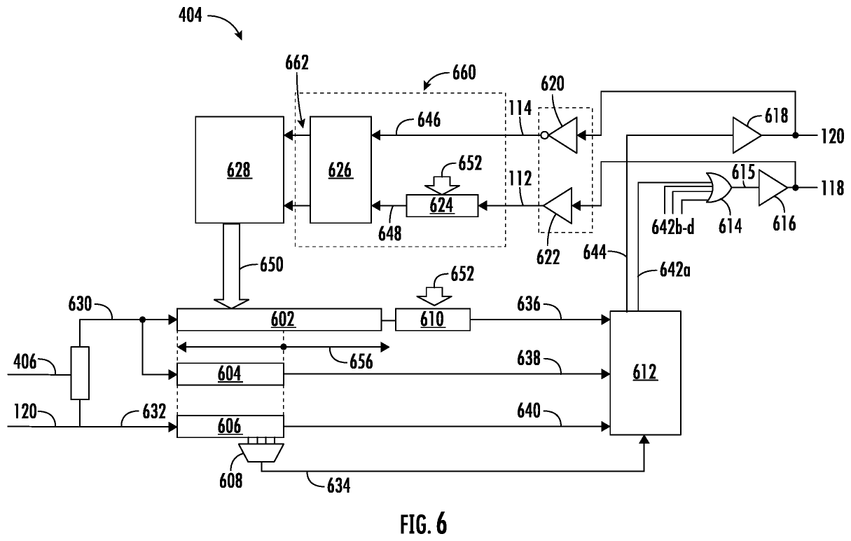

Referring now to FIG. 6, an example selection switch activation digital control circuit 404 is provided. As shown in FIG. 6, the example selection switch activation digital control circuit 404 receives the duration target code 406 from the laser pulse duration digital control circuit 402 and generates two input signals: the selection switch off signal 630 and the selection switch on signal 632, wherein the selection switch on signal 632 corresponds to the selection switch enable signal 120 and the selection switch off signal 630 is determined based on applying a delay based on the duration target code 406 to the selection switch on signal 632. From the selection switch off signal 630, two intermediate signals are generated: the selection switch off configurable delay signal 636 and the selection switch off fixed delay signal 638. In addition, a selection switch on fixed delay signal 640 is generated from the selection switch on signal 632.

As depicted in FIG. 6, the selection switch off fixed delay signal 638 is generated by transmitting the selection switch off signal 630 through a fixed delay line 604, configured to add a delay enabling adjustments to the selection switch off configurable delay signal 636 and the selection switch off fixed delay signal 638 as necessary. For example, the fixed delay line 604 may be inserted to compensate for the maximum difference in the propagation delay for the main switch driver (e.g., the delay between the assertion of the main switch enable signal 118 and the actual switch on of the main switch switching device) and the propagation delay for the selection switch driver (e.g., the delay between the de-assertion of the selection switch enable signal 120 and the actual switch off of the selection switch switching device 308). In other words, the fixed delay line 604, enables the selection switch activation digital control circuit 404 to adjust the value in the selection switch off programmable delay line 602 to generate a selection switch off configurable delay signal 636 which can anticipate the selection switch off fixed delay signal 638 if necessary. As such, in an instance in which the pulsed illumination generator circuit experiences a large propagation delay on an electrical path to the selection switch circuitry 106, the selection switch activation digital control circuit 404 mayo anticipate the selection switch off configurable delay signal 636 with respect to the selection switch off fixed delay signal 638.

The selection switch off configurable delay signal 636 is similarly generated by transmitting the selection switch off signal 630 through a selection switch off programmable delay line 602. In an instance in which the propagation delay for the selection switch driver and the propagation delay for the main switch driver are equal, the selection switch activation digital control circuit 404 may program the selection switch off programmable delay line 602 to be equal to the fixed delay line 604. In effect delaying only by the target overlap 652, programmed into the selection switch overlap programmable delay line 624. In an instance in which the propagation delay for the selection switch driver and the propagation delay for the main switch driver are not equal, the programmed propagation delays in the selection switch off programmable delay line 602 and the fixed delay line 604 will not be the equal. Thus, selection switch activation digital control circuit 404 may increase or decrease the programmed delay of the selection switch off programmable delay line 602 to compensate for this mismatch.

By utilizing the selection switch off signal 630, the fixed internal delays, and the overlap target code 650 to generate the selection switch off configurable delay signal 636, the selection switch off configurable delay signal 636 may indicate the precise time the selection switch enable command 644 may be de-asserted.

As further depicted in FIG. 6, the selection switch on fixed delay signal 640 is generated by transmitting the selection switch on signal 632 through a selection switch on fixed delay line 606, corresponding to the internal delays associated with the time between the arrival of a change in the enable signal and the transition of the signal due to the activation of the switching mechanism. In some embodiments, the programmed delay of the selection switch on fixed delay line 606 may be equivalent to the programmed delay of the fixed delay line 604.

As further depicted in FIG. 6, in an instance in which multiple channels, each having a selection switch on signal, exist, a selection switch selection mux 608 may be utilized to generate a selection mux on signal 634 indicating the assertion of any of the selection switch on signals from the multiple channels.

As further depicted in FIG. 6, the selection switch activation digital control circuit 404 includes a selection switch phase generation module 612 configured to receive at least the selection switch off configurable delay signal 636, the selection switch off fixed delay signal 638, the selection switch on fixed delay signal 640, and the selection mux on signal 634. The selection switch phase generation module 612 is further configured to generate a selection switch enable command 644 and a main switch enable command 642a. A selection switch phase generation module 612 may be any hardware, software, firmware, or combination thereof configured to receive one or more input signals and generate a plurality of output signals based on the phase of the one or more input signals. As depicted in FIG. 6, the input signals to the selection switch phase generation module 612 may comprise at least the selection switch off configurable delay signal 636, the selection switch off fixed delay signal 638, and selection switch on fixed delay signal 640. In some embodiments, the assertion of the selection switch enable command 644 may be determined based on the assertion of the selection mux on signal 634, and the de-assertion of the selection switch enable command 644 may be determined based on the assertion of the selection switch off configurable delay signal 636. Further, in some embodiments the de-assertion of the main switch enable command 642a may correspond with the selection switch on fixed delay signal 640 and the assertion of the main switch enable command 642a before the de-assertion of the selection switch enable command 644 may correspond with the selection switch off fixed delay signal 638.

As further depicted in FIG. 6, the selection switch enable command 644 is transmitted to a selection switch enable driver 618 which amplifies the selection switch enable command 644 to be transmitted as the selection switch enable signal 120 to a selection switch switching device (e.g., selection switch switching device 308) for the particular channel. As further depicted in FIG. 6, the main switch enable command 642a is transmitted to an OR logic gate 614. In some embodiments, an OR logic gate 614 may be included to receive a main switch enable command 642a-642d for each channel in a multi-channel application. Thus, a combined main switch enable command 615 is generated based on the logical combination of each of the main switch enable commands 642a-642d from the various channels. The combined main switch enable command 615 is transmitted to a main switch enable driver 616 which amplifies the combined main switch enable command 615 to be transmitted as the main switch enable signal 118 to the main switch switching device (e.g., main switch switching device 306).

As further depicted in FIG. 6, the main switch status signal 112 and the selection switch status signal 114 are utilized to generate the overlap target code 650 for the next resonance period. As depicted in FIG. 6, the example selection switch activation digital control circuit 404 further includes a selection switch overlap TDC 660 (e.g., second time-to-digital converter). The selection switch overlap TDC 660 may be any hardware, firmware, software, or combination thereof configured to receive two input signals, determine a difference between events in the signals, and output one or more signals representing the difference. In some embodiments, the selection switch overlap TDC 660 may comprise process voltage, and temperature (PVT) invariant components, for example a PVT invariant selection switch overlap programmable delay line 624. A selection switch overlap TDC 660 comprising PVT invariant components may be robust to changes in temperature and process voltage in determining the selection signal overlap offset 662 to the selection switch overlap PID 628.

As depicted in FIG. 6, the selection switch overlap TDC 660 is configured to generate an output (e.g., selection signal overlap offset 662) representing difference between the offset of the switching on of the main switch status signal 112 from the corresponding switching off of the selection switch status signal 114 and the target overlap. In some embodiments, the inverse of the selection switch status signal 114 and the main switch status signal 112 may be transmitted to a first and second input of the selection switch overlap TDC 660. As shown in FIG. 6, in some embodiments, the state of the selection switch switching device and the main switch switching device may be determined by comparators (e.g., selection switch enable comparator 620, main switch enable comparator 622) configured to compare the gate voltage of the switching device to the source voltage and determine whether the switching device is enabled or disabled.

As further depicted in FIG. 6, the selection switch overlap TDC 660 comprises a selection switch overlap phase detector 626, configured to receive a selection switch enable inverted signal 646 and a main switch enable delay signal 648. The selection switch enable inverted signal 646, may be transmitted directly to the selection switch overlap phase detector 626 from the input of the selection switch overlap TDC 660. However, the main switch enable signal 118 is transmitted through a selection switch overlap programmable delay line 624 (e.g., second programmable delay line), configured to delay the main switch status signal 112 by a target overlap 652. As described herein, the target overlap 652 may be the desired amount of time the main switch switching device is enabled before the selection switch switching device is disabled. By comparing the main switch status signal 112 delayed by the target overlap 652, with the inverse of the selection switch status signal 114, the selection switch overlap phase detector 626 may determine the offset of the disabling of the selection switch switching device from the target overlap 652.

As further depicted in FIG. 6, the selection signal overlap offset 662 output by the selection switch overlap TDC 660 is transmitted to a selection switch overlap PID 628. The selection switch overlap PID 628 may be any device comprising hardware, firmware, software, or any combination thereof configured to generate a signal based on an error between a desired signal and the actual measured value. As shown in FIG. 6, the selection switch overlap PID 628 may generate an overlap target code 650 based on the selection signal overlap offset 662 representing the difference between the selection switch enable inverted signal 646 and the main switch enable delay signal 648, delayed by the target overlap 652.

As further depicted in FIG. 6, overlap target code 650 generated based on the offset of the selection switch status signal 114 and the main switch status signal 112 from the target overlap 652 may be used to update the delay of the selection switch off programmable delay line 602, thus adjusting the overlap of the selection switch and the main switch.

Referring now to FIG. 7, an example pulsed illumination generator circuit 700 comprising four channels is provided. As depicted in FIG. 7, the example pulsed illumination generator circuit 700 includes a pulse emitting circuit 102. The pulse emitting circuit 102 is electrically connected to the input of a pulsed signal generator 124 which is subsequently electrically connected to the illumination source circuitry 108 before returning to the pulse emitting circuit 102, and electrically connected directly back to the pulse emitting circuit 102 at another output. As depicted in FIG. 7, the pulsed signal generator 124 further comprises main switch circuitry 104 and selection switch circuitry 106, connected in parallel, with the input of each electrically connected to the pulse emitting circuit 102. The output of the main switch circuitry 104 is electrically connected back to the pulse emitting circuit 102, while the output of the selection switch circuitry 106 is electrically connected in series to the input of the illumination source circuitry 108, the output of the illumination source circuitry 108 subsequently electrically connected to the pulse emitting circuit 102. As further depicted in FIG. 7, the pulsed signal generator 124 includes a switching control circuit 110, electrically connected to send and receive electronic data from the main switch circuitry 104, the selection switch circuitry 106, and the illumination source circuitry 108.

As depicted in FIG. 7, the example pulsed illumination generator circuit 700 includes four channels comprising four laser diodes 702a-702d and four switching devices 704a-704d. Each of the four switching devices 704a-704d is configured to receive a selection switch enable signal 706a-706d from the switching control circuit 110. In addition, each of the laser diodes 702a-702d is configured to produce an illumination source enabled signal 708a-708d. However, as there is only one main switching device 710, only a single main switch enable signal 712 as described in relation to FIG. 1-FIG. 6, is provided. In order to generate such signals, a laser pulse duration digital control circuit (as described in relation to FIG. 4-FIG. 5) and a selection switch activation digital control circuit (as described in relation to FIG. 5, FIG. 6) may be implemented for each of the transmission channels (CH1, CH2, CH3, CH4). A switching control circuit 110 supporting multiple channels may generate a selection switch enable command (e.g., selection switch enable command 644) for each channel and a combined main switch enable command (e.g., main switch enabled command 615 directing the behavior of the main switching device 710 in accordance with all of the channels. Although depicted as four channels in FIG. 7, the pulsed illumination generator circuit 700 may support one or more transmission channels.

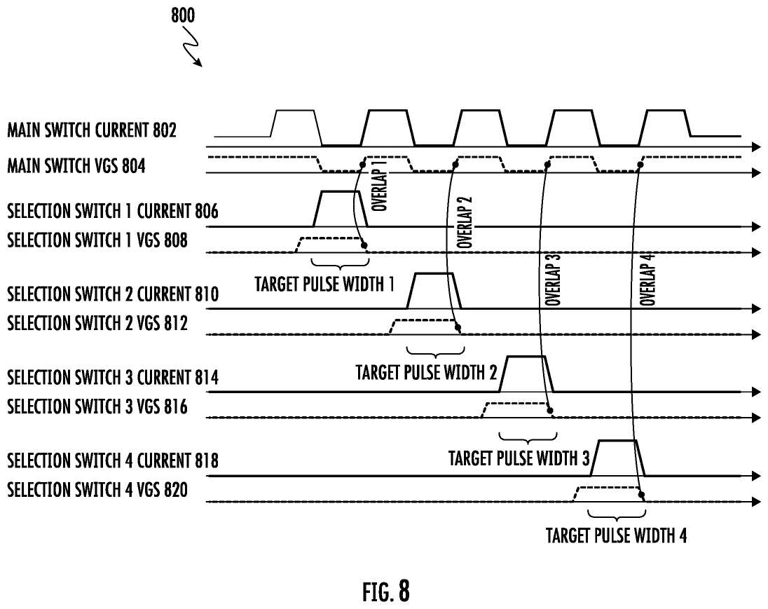

Referring now to FIG. 8, an example signal diagram 800 for an example four channel pulsed signal generator (e.g., pulsed signal generator 724) is provided. As depicted in FIG. 8, in a four channel pulsed signal generator, current (802, 806, 810, 814, 818) is switched between the main switch and each transmission channel in sequence. For example, the current flows through the main switch as indicated by main switch current 802, then selection switch one as indicated by selection switch one current 806, then back to the main switch, then selection switch two as indicated by selection switch two current 810, then back to the main switch, then selection switch three as indicated by selection switch three current 814, then back to the main switch, then selection switch four as indicated by selection switch four current 818, then finally back to the main switch. Alternating the current between the main switch and each of the four transmission channels enables control over the duration of each pulsed illumination output and enables control over the speed with which the laser diodes turn on and off. Main switch VGS 804, selection switch one VGS 808, selection switch two VGS 812, selection switch three VGS 816, and selection switch four VGS 820 depict the corresponding gate-source voltage of the selection switch switching device at each circuit, corresponding with the selection switch enable signal (e.g., selection switch enable signal 120, 706a-706d) for each transmission channel.

As further depicted in FIG. 8, the target pulse width 1, target pulse width 2, target pulse width 3, and target pulse width 4, correspond with the pulse width of the pulsed illumination output from each channel, corresponding with the selection switch enable signal (e.g., illumination source enabled signal 116, 708a-708d) and the duration target code. Further, the overlap one, overlap two, overlap three, and overlap four labels indicate the overlap between the enabling of the main switch switching device and the disabling of the selection switch switching device.

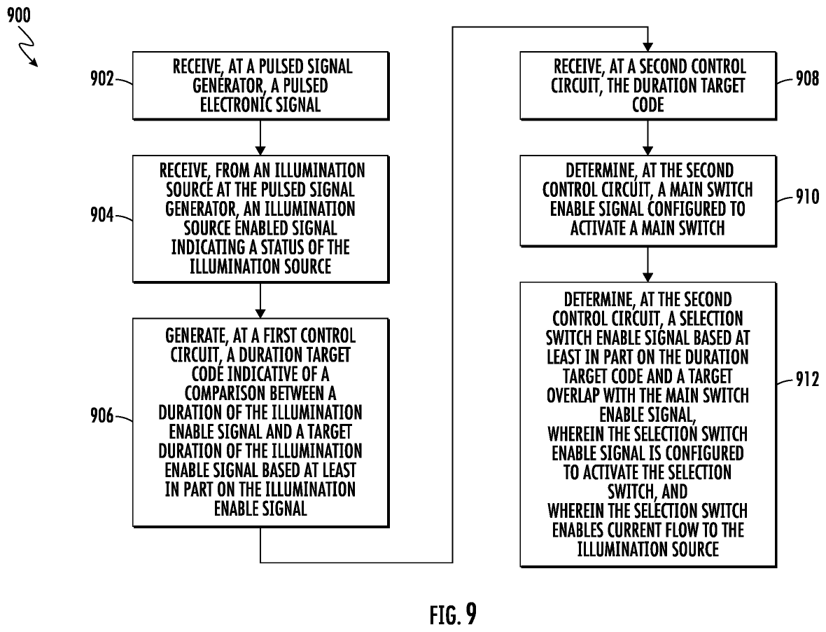

Referring now to FIG. 9, a flowchart depicting an example process 900 for generating a pulsed illumination signal (e.g., pulsed illumination signal 122) in accordance with one or more embodiments of the present disclosure. At block 902, a pulsed signal generator (e.g., pulsed signal generator 124, pulsed signal generator 724) receives a pulsed electronic signal. As described herein, a pulsed electronic signal may be generated by a pulse emitting circuit (e.g., pulse emitting circuit 102). The pulse emitting circuit may generate the pulsed electronic signal at a particular resonance frequency. In some embodiments, the pulsed signal generator may be configured to enable multiple transmission channels during a single resonance period of the pulsed electronic signal.

At block 904, the pulsed signal generator receives, from an illumination source, an illumination source enabled signal (e.g., illumination source enabled signal 116, 708a-708d) indicating a status of the illumination source. As described herein, in some embodiments, the illumination source enabled signal may be generated based at least in part on the voltage at the anode at a laser diode or other illumination source. The illumination source enabled signal may indicate whether the illumination source is illuminated, or off.

At block 906, the pulsed signal generator generates, at a first control circuit, a duration target code (e.g., duration target code 406) indicative of a comparison between a duration of the illumination enable signal and a target duration of the illumination enable signal based at least in part on the illumination enable signal. As described herein, in some embodiments, the pulsed signal generator may comprise a first control circuit configured to determine a duration target code based on a desired target duration. The desired target duration may indicate the desired pulse width of a pulsed illumination output, and the duration target code indicates the adjustment to the selection switch enable signal necessary to obtain the desired target duration.

In some embodiments, the pulsed signal generator may further generate, at a first time-to-digital converter (TDC) (e.g., pulse width TDC 514) of the first control circuit, an illumination target off signal (e.g., illumination target off signal 512) by delaying the illumination source enabled signal by the target duration. Further, the pulsed signal generator may determine, at a first phase detector (e.g., pulse width phase detector 506) of the first control circuit, an illumination signal offset (e.g., illumination signal offset 516) between the illumination source enabled signal and an inverse of the illumination target off signal. Further, the pulsed signal generator may receive, at a first proportional-integral-derivative controller (e.g., pulse width PID 508), the illumination signal offset and generate the duration target code based on the illumination signal offset.

At block 908, the pulsed signal generator receives, at a second control circuit (e.g., selection switch activation digital control circuit 404), the duration target code. In some embodiments, the second control circuit is designed as a cascade of the first control circuit. Thus, changes in the duration target code do not effect the overlap target code, and vice versa.

At block 910, the pulsed signal generator determines, at the second control circuit, a main switch enable signal (e.g., main switch enable signal 118) configured to activate a main switch (e.g., main switch switching device 306, main switching device 710). In some embodiments, the main switch enable signal may activate and deactivate the main switch switching device in the pulsed signal generator, thus allowing the flow of current through the main switch circuitry. The main switch enable signal may be synchronized with the selection switch enable signal (e.g., selection switch enable signal 120) to control the switching on and switching off speed of the pulsed illumination output.

At block 912, the pulsed signal generator determines, at the second control circuit, a selection switch enable signal based at least in part on the duration target code and a target overlap with the main switch enable signal, wherein the selection switch enable signal is configured to activate the selection switch (e.g., selection switch switching device 308, selection switch switching devices 704a-704d), and wherein the selection switch enables current flow to the illumination source (e.g., laser diode 310, 702a-702d). As described herein, the selection switch enable signal may be synchronized with the main switch enable signal to control the pulsed illumination output. For example, a short overlap of time in which the main switch and the selection switch are enabled may increase the speed at which the illumination source turns off, enabling improvements in measurements of received reflections.

In some embodiments, the block 910 and 912 may further include receiving, at a second time-to-digital converter (e.g., selection switch overlap TDC 660) of the second control circuit, a selection switch status signal (e.g., selection switch status signal 114), and a main switch status signal wherein the selection switch status signal is based at least in part on the selection switch enable signal (e.g., selection switch enable signal 120), and wherein the main switch status signal (e.g., main switch status signal 112) is based at least in part on the main switch enable signal (e.g., main switch enable signal 118), and determining a selection signal offset based at least in part on a time difference between the target overlap and an overlap of the selection switch status signal and the main switch status signal.

In addition, the pulsed signal generator may receive, at a second proportional-integral-derivative controller (e.g., selection switch overlap PID 628) of the second control circuit, the selection signal offset, and generate an overlap target code (e.g., overlap target code 650) based at least in part on the selection signal offset.

In some embodiments, the pulsed signal generator may receive, at an illumination signal off programmable delay line (e.g., selection switch off programmable delay line 602) of the second control circuit, the overlap target code and the target overlap, and generate an illumination off signal (e.g., selection switch off configurable delay signal 636) based at least in part on the overlap target code and the target overlap.

Referring now to FIG. 10, an example LIDAR system 1000 is provided. As depicted in FIG. 10, the example LIDAR system 1000 includes a controller 1002 configured to control a pulse emitting circuit 102 electrically connected to a pulsed signal generator 124 and illumination source circuitry 108 configured to generate pulsed illumination output 126 upon receipt of a pulsed illumination signal 122 from the switching control circuit (e.g., switching control circuit 110). The controller 1002 is further configured to receive reflected pulsed illumination 1006 through an emitted pulse receiver 1004.

As depicted in FIG. 10, the example LIDAR system 1000 includes a controller 1002. In an example embodiment, the controller 1002 is configured to execute instructions stored in a data storage media or otherwise accessible to the controller 1002. Alternatively or additionally, the controller 1002 in some embodiments is configured to execute hard-coded functionality. As such, whether configured by hardware or software methods, or by a combination thereof, the controller 1002 represents an entity (e.g., physically embodied in circuitry) capable of performing operations according to an embodiment of the present disclosure while configured accordingly. Alternatively or additionally, as another example in some example embodiments, when the controller 1002 is embodied as an executor of software instructions, the instructions specifically configure the controller 1002 to perform the algorithms embodied in the specific operations described herein when such instructions are executed.

For example, in some embodiments, the controller 1002 may be configured to perform various operations associated with configuring the pulse emitting circuit 102 and pulsed signal generator 124. Operations may include but are not limited to configuring the resonance period of the pulse emitting circuit 102, configuring the target pulse width and the target overlap in the pulsed signal generator 124, and so on.

As depicted in FIG. 10, the illumination source circuitry 108 may be configured to control the pulsed illumination output 126 from one or more laser diodes (e.g., laser diode 310, laser diodes 702a-702d). As described herein, the pulsed illumination output 126 may be determined for the one or more laser diodes by a switching control circuit (e.g., switching control circuit 110) configured to produce one or more illumination source enabled signals (e.g., illumination source enabled signal 116, illumination source enabled signal 510, illumination source enabled signals 708a-708d) and one or more selection switch enable signals (e.g., selection switch enable signal 120, selection switch enable signals 706a-706d).

Additionally, the controller 1002 may be configured to receive electrical signals based on the reflected pulsed illumination 1006 received by an emitted pulse receiver 1004 and perform signal processing operations to determine certain characteristics of the received signal. The controller 1002 may further determine time-of-flight measurements based on a comparison of the reflected pulsed illumination 1006 with the pulsed illumination output 126. Time-of-flight measurements may enable the controller 1002 to determine the distance of objects in the surrounding environment.

As further depicted in FIG. 10, the example LIDAR system 1000 may include an emitted pulse receiver 1004, configured to receive reflected pulsed illumination 1006 and transmit corresponding electrical signals to the controller 1002. An emitted pulse receiver 1004 may be any electronic sensor or device configured to detect reflected light and convert the light into electrical energy. In some embodiments, the emitted pulse receiver 1004 may comprise a photodiode, an avalanche photodiode, silicon photomultiplier, PIN photodiode, or other similar detector.

While this detailed description has set forth some embodiments of the present invention, the appended claims cover other embodiments of the present invention which differ from the described embodiments according to various modifications and improvements. For example, one skilled in the art may recognize that such principles may be applied to any electronic device that utilizes pulsed electronic signals requiring high precision. For example, various LIDAR systems, time-of-flight cameras, ultrasonic distance sensors, and other similar devices.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. An electronic system comprising:
a pulse emitting circuit electrically connected to an illumination source; and
a pulsed signal generator comprising:
a main switch electrically connected to the pulse emitting circuit;
a selection switch electrically connected to the main switch,
wherein the selection switch controls a current flow to the illumination source; and
a switching control circuit comprising:
a first control circuit,
wherein the first control circuit receives an illumination source enabled signal indicating a status of the illumination source, and
wherein the first control circuit generates a duration target code indicative of a comparison between a duration of the illumination source enabled signal and a target duration of the illumination source enabled signal; and
a second control circuit,
wherein the second control circuit receives the duration target code, and
wherein the second control circuit determines a main switch enable signal configured to activate the main switch and a selection switch enable signal configured to activate the selection switch, based at least in part on the duration target code and a target overlap.

2. The electronic system of claim 1, wherein the first control circuit of the switching control circuit further comprises a first time-to-digital converter (TDC),
wherein the first TDC is configured to determine an illumination signal offset between the duration of the illumination source enabled signal and the target duration of the illumination source enabled signal.

3. The electronic system of claim 2, wherein the first control circuit further comprises a first proportional-integral-derivative controller configured to generate the duration target code based on the illumination signal offset.

4. The electronic system of claim 1, wherein the second control circuit further comprises a second time-to-digital converter (TDC) configured to determine a selection signal offset,
wherein the selection signal offset represents a time difference between the target overlap and an overlap of a selection switch status signal and a main switch status signal,
wherein the selection switch status signal is based at least in part on the selection switch enable signal, and
wherein the main switch status signal is based at least in part on the main switch enable signal.

5. The electronic system of claim 4, wherein the second control circuit further comprises a second proportional-integral-derivative controller configured to generate an overlap target code based on the selection signal offset.

6. The electronic system of claim 5, wherein the second control circuit further comprises an illumination signal off programmable delay line configured to generate an illumination off signal based on the overlap target code and the target overlap.

7. The electronic system of claim 6, wherein the second control circuit de-asserts the selection switch enable signal based on the illumination off signal.

8. The electronic system of claim 1, further comprising a plurality of selection switches, and a plurality of switching control circuits, each switching control circuit associated with a selection switch.

9. The electronic system of claim 5, wherein the second control circuit is a cascade of the first control circuit, such that adjustments to the duration target code do not affect the overlap target code and adjustments to the overlap target code do not affect the duration target code.

10. A method for generating a pulsed illumination signal, the method comprising:
receiving, at a pulsed signal generator, a pulsed electronic signal;
receiving, from an illumination source at the pulsed signal generator, an illumination source enabled signal indicating a status of the illumination source;
generating, at a first control circuit, a duration target code indicative of a comparison between a duration of the illumination source enabled signal and a target duration of the illumination source enabled signal based at least in part on the illumination source enabled signal;
receiving, at a second control circuit, the duration target code;
determining, at the second control circuit, a main switch enable signal configured to activate a main switch;
determining, at the second control circuit, a selection switch enable signal based at least in part on the duration target code and a target overlap with the main switch enable signal,
wherein the selection switch enable signal is configured to activate a selection switch, and
wherein the selection switch enables current flow to the illumination source; and
generating a pulsed illumination signal based at least in part on the selection switch enable signal.

11. The method of claim 10, the method further comprising:
determining, at a first time-to-digital converter (TDC) of the first control circuit, an illumination signal offset between the duration of the illumination source enabled signal and the target duration of the illumination source enabled signal.

12. The method of claim 11, the method further comprising:
receiving, at a first proportional-integral-derivative controller, the illumination signal offset; and
generating the duration target code based on the illumination signal offset.

13. The method of claim 10, the method further comprising:
receiving, at a second time-to-digital converter of the second control circuit, a selection switch status signal and a main switch status signal,
wherein the selection switch status signal is based at least in part on the selection switch enable signal, and
wherein the main switch status signal is based at least in part on the main switch enable signal; and
determining a selection signal offset based at least in part on a time difference between the target overlap and an overlap of the selection switch status signal and the main switch status signal.

14. The method of claim 13, the method further comprising:
receiving, at a second proportional-integral-derivative controller of the second control circuit, the selection signal offset; and
generating an overlap target code based at least in part on the selection signal offset.

15. The method of claim 14, the method further comprising:
receiving, at an illumination signal off programmable delay line of the second control circuit, the overlap target code and the target overlap; and
generating an illumination off signal based at least in part on the overlap target code and the target overlap.

16. The method of claim 15, the method further comprising:
de-asserting the selection switch enable signal based at least in part on the illumination off signal.

17. The method of claim 10, wherein the pulsed signal generator further comprises a plurality of selection switches, and a plurality of switching control circuits, each switching control circuit associated with a selection switch.

18. The method of claim 14, wherein the second control circuit is a cascade of the first control circuit, such that adjustments to the duration target code do not affect the overlap target code and adjustments to the overlap target code do not affect the duration target code.

19. A light detection and ranging (LIDAR) system comprising:
a controller;
a pulse emitting circuit electrically connected to the controller and an illumination source,
wherein the illumination source is configured to generate a light output based at least in part on an illumination source enabled signal;
a pulsed signal generator comprising:
a main switch electrically connected to the pulse emitting circuit;
a selection switch electrically connected to the main switch,
wherein the selection switch controls a current flow to the illumination source; and
a switching control circuit comprising:
a first control circuit,
wherein the first control circuit receives the illumination source enabled signal indicating a status of the illumination source, and
wherein the first control circuit generates a duration target code indicative of a comparison between a duration of the illumination source enabled signal and a target duration of the illumination source enabled signal; and
a second control circuit,
wherein the second control circuit receives the duration target code, and
wherein the second control circuit determines a main switch enable signal configured to activate the main switch and a selection switch enable signal configured to activate the selection switch, based at least in part on the duration target code and a target overlap; and
an emitted pulse receiver electrically connected to the controller and configured to receive a reflection of the light output off an object;
wherein the controller is configured to determine a distance of the object based on the reflection of the light output.

20. The light detection and ranging (LIDAR) system of claim 19, wherein the pulsed signal generator further comprises a plurality of selection switches, and a plurality of switching control circuits, each switching control circuit associated with a selection switch.
